(19) United States
(12) Patent Application Publication
(10) Pub. No.: US 2007/0014925 A1
(43) Pub. Date: Jan. 18, 2007

(54) Method for slot extrusion coating a liquid composition

(75) Inventor: Willem Mues, Tremelo (BE)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(73) Assignee: AGFA-GEVAERT, Mortsel (BE)

(21) Appl. No.: 11/483,990

(22) Filed: Jul. 10, 2006

Related U.S. Application Data
(60) Provisional application No. 60/713,701, filed on Sep. 2, 2005.

(30) Foreign Application Priority Data
Jul. 13, 2005 (EP) 05106412.9

(51) Int. Cl. B05D 3/12; C23C 16/52

(52) U.S. Cl. 427/355; 427/8

(57) ABSTRACT

A method for slot extrusion coating a liquid composition at a coating temperature and a coating speed at or above 40 m/min, said liquid composition having a viscosity at said coating temperature of at least 500 mPa·s at a shear rate of 100 s⁻¹, comprising the step of: (i) selecting said liquid composition for slot extrusion coating having a tan δ of less than 1000 measured by oscillatory dynamic viscosity measurements at 1 Hz, the coating temperature and a shear stress of 250 Pa under conditions in which there is effectively no variation in shear stress within said liquid composition during said measurement, said liquid composition being selected from liquid compositions each comprising at least one binder and a liquid carrier medium; and (ii) slot extrusion coating the composition via a slot onto a web support with a bead vacuum at the coating temperature and the coating speed.

This application claims the benefit of U.S. Provisional Application No. 60/713,701 filed Sep. 2, 2005, which is incorporated by reference. In addition, this application claims the benefit of European Application No. 05106412.9 filed Jul. 13, 2005, which is also incorporated by reference.

### FIELD OF THE INVENTION

The present invention relates to a method for slot extrusion coating of a liquid composition and a method for selecting a liquid composition for slot extrusion coating.

### BACKGROUND OF THE INVENTION

Coatings are generally applied as a uniform, continuous layer. Slot extrusion coating is just one way to coat a composition onto a substrate, as many other methods are available such as coating by curtain, knife or blade, forward-roll, reverse roll, or slide methods. Slot extrusion coating is particularly useful for applying coatings at high substrate speeds and for precision applications. Coating by slot extrusion can provide precise, premetered quantities of a composition. In general, slot extrusion coating is used to deliver thin sheets of material (e.g. coating) onto a substrate by feeding fluid to a coating slot (die), which in turn, applies the fluid to a substrate in the form of a sheet or film.

Many studies have been performed to understand or model the dynamics and other behavioural effects liquid compositions exhibit during coating operations. For example, rheology, shear thinning, viscosity, elasticity, Newtonian or non-Newtonian flow, inertial effects and extensional effects, to name just a few, have been the subject of coating studies. Of particular interest in studying these effects and characteristics is the manageability and optimization of coating methods to achieve coatings less susceptible to drying defects. The coatability of a composition in combination with a particular coating technique is an area of interest, especially for operations that desire thin coatings, use high solids content, or both.

The simplest method of coating is to dip the substrate in a liquid bath and then withdrawing the substrate. The air entrapped with the substrate is thereby replaced by liquid. The free liquid surface parts upon the entry of the substrate in the dynamic contact line. If the dynamic contact angle θ_{dyn} approaches 180° an air layer is trapped which is unstable and breaks up into bubbles. These air bubbles adversely affect the coating process and the resulting coating. This phenomenon is known as “air entrainment”. The critical coating speed above which air entrainment occurs (Uₐₑ) is dependent upon the chemical and physical properties of the liquid and the substrate (e.g. roughness). The viscosity of the liquid is, however, the most important parameter. Gutoff and Kendrick in 1982 reported in the American Institute of Chemical Engineers (AIChE) Journal, volume 28, page 1283, the following empirically determined correlation:
Uₐₑ=5.11.η^{-0.67}
where Uₐₑ is the critical coating speed up to which air entrainment occurs in m/s and η is the viscosity in mPa·s. Liquids with a high solids concentration have a high viscosity, which means that the critical coating speed above which air entrainment occurs is extremely low with such liquids.

Modern coating systems have the advantage over simple dip-coating of employing a geometry which suppresses air entrainment, thereby shifting the critical coating speed for air entrainment to higher coating speeds by changing the direction and strength of the forces equilibrating at the three-phase point (hydrodynamic assistance). The use of vacuum, gravitational forces and, in the case of curtain coating, electrostatic forces all result in an increase in the critical coating speed above which air entrainment occurs, due to the resulting changes in the geometry of the coating bead spanning the gap between the slot and the substrate.

Application of a vacuum behind the coating bead, so-called bead vacuum, modifies the shape of the bead, the part of the bottom meniscus near the slide surface can as a result be concave upwards. The bead vacuum, P, is here defined as P_{atmospheric}-P_{vacuum} chamber. Increasing the bead vacuum above a particular bead vacuum in cascade or slot coating causes other coating defects to occur, the principal ones being known variously as bead break-up, bead instability, meniscus rupture or rivulet formation; and ribbing.

At a particular coating speed for a particular coating liquid, the critical vacuum below which air entrainment is observed is defined as Pₘᵢₙ and the critical vacuum above which bead break-up occurs is defined as Pₘₐₓ. The vacuum range between Pₘᵢₙ and Pₘₐₓ for a particular coating speed, particular coating liquid and particular coating temperature within which air entrainment, bead break-up and ribbing are absent is defined as the window of coatability, ΔP.

Optimal utilization of the coating capacity of a coating apparatus dictates that a coating liquid be coated at the maximum coating speed that the drying unit in the coating apparatus will permit. However, with increasing coating speed the sensitivity of the coating to air entrainment will increase with coating speed and hence Pₘᵢₙ. The vacuum required to suppress air entrainment, will also increase with coating speed. Furthermore, the increased liquid supply necessary to maintain a constant wet-layer thickness with increasing coating speed results in an increase in Pₘₐₓ with increasing coating speed. A decrease in the window of coatability, ΔP, is observed with increasing coating speed, because Pₘᵢₙ increases faster with coating speed than Pₘₐₓ and hence at a particular coating speed Pₘᵢₙ will be equal to Pₘₐₓ. The coating speed for a particular liquid at a particular temperature at which Pₘᵢₙ equals Pₘₐₓ is known as the maximum coating speed Uₘₐₓ.

At a constant coating speed, coating temperature and constant wet-layer thickness, Pₘᵢₙ can be reduced by decreasing the viscosity of the coating liquid e.g. by using lower molecular weight binders or diluting the coating liquid with further carrier liquid. However, properties of the coated layer can dictate that a particular wet-layer thickness not be exceeded, whereas dilution with further carrier liquid results in an increase in wet-layer thickness. Moreover, dilution with further carrier liquid also results in more solvent having to be evaporated during the drying process and a reduction in the resistance of the wet layer to the gas currents involved in the drying process leading to deterioration in the smoothness of the dried layer.

It is desirable for the slot extrusion coating of a particular high viscosity composition, that the window of coatability be as large as possible to compensate for possible variation in the properties of the components of the high viscosity composition. A method is therefore required, which can indicate whether a particular high viscosity composition will be slot extrusion coatable within a significant vacuum range.

### ASPECTS OF THE INVENTION

It is therefore an aspect of the present invention to provide a method for selecting a liquid composition for slot extrusion coating, which can indicate whether or not a particular high viscosity composition will be slot extrusion coatable within a significant vacuum range.

It is a further aspect of the present invention to provide a method for slot extrusion coating with a liquid composition selected by a method for selecting a liquid composition for slot extrusion coating, which can indicate whether or not a particular high viscosity composition will be slot extrusion coatable within a significant vacuum range.

Further aspects and advantages of the invention will become apparent from the description hereinafter.

### SUMMARY OF THE INVENTION

It has been surprisingly found that for coating liquid compositions with different binders at a particular temperature, the liquid compositions having a viscosity greater than 500 mPa·s at a shear rate of 100 s⁻¹ at the coating temperature, that the tan δ value of the liquid compositions in the slot extrusion coating process measured under low frequency oscillation e.g. 1 Hz with a shear stress >>1 Pa e.g. 250 Pa provides an indication of whether or not the liquid compositions will be slot extrusion coatable at a coating speed at or above 40 m/min within a significant vacuum range without air entrainment, bead break-up or ribbing. Moreover, the size of this window of coatability has been found to increase as the tan δ value decreases.

Aspects of the present invention have been realized by a method for slot extrusion coating a liquid composition at a coating temperature and a coating speed at or above 40 m/min, the liquid composition having a viscosity at the coating temperature of at least 500 mPa·s at a shear rate of 100 s⁻¹, comprising the steps of: (i) selecting the liquid composition for slot extrusion coating having a tan δ of less than 1000 measured by oscillatory dynamic viscosity measurements at 1 Hz, the coating temperature and a shear stress of 250 Pa under conditions in which there is effectively no variation in shear stress within the liquid composition during the measurements, the liquid composition being selected from liquid compositions each comprising at least one binder and a liquid carrier medium; and (ii) slot extrusion coating the composition via a slot onto a web support with a bead vacuum at the coating temperature and the coating speed.

Aspects of the present invention have also been realized by a method for selecting a liquid composition for slot extrusion coating at a coating temperature and a coating speed at or above 40 m/min, the liquid composition having a viscosity at the coating temperature of at least 500 mPa·s at a shear rate of 100 s⁻¹, comprising the step of: (i) selecting the liquid composition for slot extrusion coating having a tan δ of less than 1000 measured by oscillatory dynamic viscosity measurements at 1 Hz, the coating temperature and a shear stress of 250 Pa under conditions in which there is effectively no variation in shear stress within the liquid composition during the measurements, the composition being selected from liquid compositions each comprising at least one binder and a liquid carrier medium.

Preferred embodiments are disclosed in the dependent claims.

### DETAILED DESCRIPTION OF THE INVENTION

### Definitions

It is noted that the terms “first,” “second,” and the like, herein do not denote any amount, order, or importance, but rather are used to distinguish one element from another.

Coating bead is defined herein as the bridge of liquid spanning the gap between a slot and a substrate

The term “bead vacuum”, represented by P, is here defined, for the purposes of disclosing the present invention, as P_{atmospheric}-P_{vacuum chamber}.

Pₘᵢₙ is here defined, for the purposes of disclosing the present invention, as the critical bead vacuum below which air entrainment is observed for a particular coating liquid at a particular coating speed and coating temperature.

Pₘₐₓ is here defined, for the purposes of disclosing the present invention, as the critical bead vacuum above which bead break-up is observed for a particular coating liquid at a particular coating speed and coating temperature.

The vacuum range between Pₘᵢₙ and Pₘₐₓ within which air are absent for a particular coating speed, particular coating liquid and particular coating temperature is known, for the purposes of disclosing the present invention, as the window of operability, ΔP, i.e. ΔP=Pₘₐₓ-Pₘᵢₙ.

Uₘₐₓ is the maximum coating speed for a particular liquid at a particular temperature and is the coating speed at which Pₘᵢₙ equals Pₘₐₓ.

The term aqueous medium means a medium containing water and water-miscible organic solvents containing between 50% by weight of water and 100% by weight of water.

PET as used in the present disclosure represents poly(ethylene terephthalate).

The term thermographic recording material, as used in disclosing the present invention, includes substantially light-insensitive thermographic recording materials and photothermographic recording materials.

The term “polyvinyl acetal”, as used in disclosing the present invention, is the condensation product of polyvinyl alcohol and one or more aldehydes.

The term “polyvinyl butyral”, as used in disclosing the present invention, is the condensation product of polyvinyl alcohol and butyraldehyde.

The term “polyvinyl aceto-acetal”, as used in disclosing the present invention, is the condensation product of polyvinyl alcohol and acetaldehyde.

The term colorant, as used in disclosing the present invention, includes both dyes and pigments.

The term dye, as used in disclosing the present invention, means a coloring agent having a solubility of 10 mg/L or more in the medium in which it is applied and under the ambient conditions pertaining.

The term pigment is defined in DIN 55943, herein incorporated by reference, as used in disclosing the present invention, is an inorganic or organic, chromatic or achromatic colouring agent that is practically insoluble in the application medium under the pertaining ambient conditions, hence having a solubility of less than 10 mg/L therein.

### Method for Slot Extrusion Coating

For liquid compositions with a viscosity at the coating temperature of at least 500 mPa·s at a shear rate of 100 s⁻¹, a significant window of coatability is realized at a coating speed at or above 40 m/min, if the liquid composition has a tan δ of less than 1000, when measured by oscillatory dynamic viscosity measurements at 1 Hz, the coating temperature and a shear stress of 250 Pa under conditions in which there is effectively no variation in shear stress within the liquid composition during the measurements. Pₘᵢₙ values in the range of 0.9 to 2.2 kPa have been realized, according to the method for slot extrusion coating, and Pₘₐₓ values in the range of 2.5 to 4.6 kPa have been realized according to the method for slot extrusion coating, according to the present invention, resulting in windows of coatability, ΔP, of up to 3.1 kPa in an experimental configuration and of greater than 3.5 kPa (Pₘₐₓ was not attained due to the limitations of the vacuum unit used) in a full production configuration, with windows of coatability of >1.0 kPa being preferred and >1.5 kPa being particularly preferred.

According to a first embodiment of method for slot extrusion coating, according to the present invention, tan δ is less than 500 measured by oscillatory dynamic viscosity measurements at 1 Hz, the coating temperature and a shear stress of 250 Pa.

According to a second embodiment of method for slot extrusion coating, according to the present invention, tan δ is less than 200 measured by oscillatory dynamic viscosity measurements at 1 Hz, the coating temperature and a shear stress of 250 Pa.

According to a third embodiment of method for slot extrusion coating, according to the present invention, tan δ is greater than 1 measured by oscillatory dynamic viscosity measurements at 1 Hz, the coating temperature and a shear stress of 250 Pa.

According to a fourth embodiment of method for slot extrusion coating, according to the present invention, tan δ is greater than 10 measured by oscillatory dynamic viscosity measurements at 1 Hz, the coating temperature and a shear stress of 250 Pa.

According to a fifth embodiment of the method for slot extrusion coating, according to the present invention, wherein the viscosity of the liquid composition is greater than 600 mPa·s at the coating temperature and 100 s⁻¹.

According to a sixth embodiment of the method for slot extrusion coating, according to the present invention, the viscosity of the liquid composition is greater than 700 mPa·s at the coating temperature and 100 s⁻¹.

According to a seventh embodiment of the method for slot extrusion coating, according to the present invention, the viscosity of the liquid composition is less than 5000 mPa·s at the coating temperature and 100 s⁻¹.

According to an eighth embodiment of the method for slot extrusion coating, according to the present invention, the coating speed is at or above 60 m/min.

According to a ninth embodiment of the method for slot extrusion coating, according to the present invention, wherein the coating speed is at or above 70 m/min.

According to a tenth embodiment of the method for slot extrusion coating, according to the present invention, the at least one binder is a polyvinyl acetal.

According to an eleventh embodiment of the method for slot extrusion coating, according to the present invention, the at least one binder is polyvinyl butyral or a copolymer comprising vinyl aceto-acetal and vinyl butyral units.

According to a twelfth embodiment of the method for slot extrusion coating, according to the present invention, the liquid composition further comprises fine particles e.g. pigment particles, magnetic pigments, silica, alumina and clay.

According to a thirteenth embodiment of method for slot extrusion coating, according to the present invention, wherein the liquid composition further comprises a substantially light-insensitive organic silver salt.

According to a fourteenth embodiment of the method for slot extrusion coating, according to the present invention, the liquid composition further comprises an organic reducing agent.

According to a fifteenth embodiment of the method for slot extrusion coating, according to the present invention, the liquid composition comprises at least one surfactant and/or at least one dispersant.

According to a sixteenth embodiment of the method for slot extrusion coating, according to the present invention, the liquid carrier medium is non-aqueous.

According to a seventeenth embodiment of the method for slot extrusion coating, according to the present invention, the liquid composition further comprises a colorant.

According to an eighteenth embodiment of the method for slot extrusion coating, according to the present invention, the method further comprises the step of drying and the resulting dried layer is a thermosensitive element of a thermographic recording material.

According to a nineteenth embodiment of the method for slot extrusion coating, according to the present invention, the gap between the slot and the web support is less than 10 times the wet layer thickness of the coating.

### A method for Selecting a Liquid Composition for Slot Extrusion Coating

According to a first embodiment of method for selecting a liquid composition for slot extrusion coating, according to the present invention, tan δ is less than 500 measured by oscillatory dynamic viscosity measurements at 1 Hz, the coating temperature and a shear stress of 250 Pa.

According to a second embodiment of method for selecting a liquid composition for slot extrusion coating, according to the present invention, tan δ is less than 200 measured by oscillatory dynamic viscosity measurements at 1 Hz, the coating temperature and a shear stress of 250 Pa.

According to a third embodiment of method for selecting a liquid composition for slot extrusion coating, according to the present invention, tan δ is greater than 1 measured by oscillatory dynamic viscosity measurements at 1 Hz, the coating temperature and a shear stress of 250 Pa.

According to a fourth embodiment of method for selecting a liquid composition for slot extrusion coating, according to the present invention, tan δ is greater than 10 measured by oscillatory dynamic viscosity measurements at 1 Hz, the coating temperature and a shear stress of 250 Pa.

According to a fifth embodiment of the method for selecting a liquid composition for slot extrusion coating, according to the present invention, the viscosity of the liquid composition is greater than 600 mPa·s at the coating temperature and 100 s⁻¹.

According to a sixth embodiment of the method for selecting a liquid composition for slot extrusion coating, according to the present invention, the viscosity of the liquid composition is greater than 700 mPa·s at the coating temperature and 100 s⁻¹.

According to a seventh embodiment of the method for selecting a liquid composition for slot extrusion coating, according to the present invention, the viscosity of the liquid composition is less than 5000 mPa·s at the coating temperature and 100 s⁻¹.

According to an eighth embodiment of the method for selecting a liquid composition for slot extrusion coating, according to the present invention, the coating speed is at or above 60 m/min.

According to a ninth embodiment of the method for selecting a liquid composition for slot extrusion coating, according to the present invention, the coating speed is at or above 70 m/min.

According to a tenth embodiment of the method for selecting a liquid composition for slot extrusion coating, according to the present invention, the at least one binder is a polyvinyl acetal.

According to an eleventh embodiment of the method for selecting a liquid composition for slot extrusion coating, according to the present invention, the at least one binder is polyvinyl butyral or a copolymer comprising vinyl aceto-acetal and vinyl butyral units.

According to a twelfth embodiment of the method for selecting a liquid composition for slot extrusion coating, according to the present invention, the liquid composition further comprises fine particles e.g. pigment particles, magnetic pigments, silica, alumina and clay.

According to a thirteenth embodiment of the method for selecting a liquid composition for slot extrusion coating, according to the present invention, the liquid composition further comprises a substantially light-insensitive organic silver salt.

According to a fourteenth embodiment of the method for selecting a liquid composition for slot extrusion coating, according to the present invention, the liquid composition further comprises an organic reducing agent.

According to a fifteenth embodiment of the method for selecting a liquid composition for slot extrusion coating, according to the present invention, the liquid composition comprises at least one surfactant and/or at least one dispersant.

According to a sixteenth embodiment of the method for selecting a liquid composition for slot extrusion coating, according to the present invention, the liquid carrier medium is non-aqueous.

According to a seventeenth embodiment of the method for selecting a liquid composition for slot extrusion coating, according to the present invention, the liquid composition further comprises a colorant.
tan δ

tan δ, as used in disclosing the present invention, is defined as the ratio of the loss modulus (viscous component of the liquid, G″) to the elastic modulus (storage component of the liquid, G′), where G′ is the ratio of the stress in phase with the strain to the strain, and G″ is the ratio of the stress 90° out of phase with the strain to the strain. G′ and G″ are commonly combined as the real and imaginary parts of the complex dynamic modulus G* which is a function of the frequency of shearing ω:
G*(ω)=G′(ω)+jG″(ω)
Alternatively to the complex modulus G*(ω) a complex viscosity η* can be defined:
η*=G*/ω=τ₀/γ₀·ω=η′(ω)+jη″(ω)
where τ₀ and γ₀ are the zero-order strain and stress respectively. It describes the total resistance to a dynamic shear. It can also be broken down into two components: the dynamic viscosity, η, the viscous component, and the storage (out of phase) viscosity η″, the elastic component. At low frequencies η′ approaches the viscosity measured in steady shear as the shear rate approaches zero.

The dynamic viscosity, η′, and the storage viscosity, η″, are related to G′and G″ by the expressions: η′=G″/ω; and η″=G′/ω.

The degree of resilience of a liquid increases with decreasing tan δ. A correlation has been surprisingly established between the coating window realized in slot extrusion coating and tan δ determined under specific oscillation frequencies and shear stresses.

Ideally, since elongational stress is present in slot extrusion coating, tan δ should be determined by viscosity measurements under oscillatory elongational stress. However, there are no commercially available apparatuses of this type. However, apparatuses are commercially available in which viscosity measurements are carried out under oscillatory rotational stress e.g. from Gebrüder Haake GmbH, Rheometrics Inc., e.g. Dynamic Stress Rheometer, and Anton Paar GmbH e.g. the Physica MCR 501.

It has been found that for dispersions using the same binder or different binders or binder mixtures, the tan δ values determined at a shear stress of 250 Pa and oscillation frequencies of 1 Hz or 10 Hz decrease with increasing window of coatability, ΔP, as represented by the vacuum range between Pₘₐₓ and Pₘᵢₙ at a given coating speed. Therefore, the lower the tan δ value the higher the window of coatability.

An oscillatory frequency of 1 Hz is preferred to one of 10 Hz, since tan δ values obtained from measurements carried out at an oscillatory frequency of 1 Hz exhibit greater variation with coating liquid composition. Furthermore, it was found that tan δ values increase strongly with increasing shear stress. This means that the viscosity measurements have to be carried out under conditions in which there is effectively no variation in shear stress within the liquid composition. Therefore, concentric cylinder viscosity measurements are preferred to cone-plate viscosity measurements. Moreover, only one measurement can be carried out per sample, due to memory effects due to the viscoelastic nature of the samples. Furthermore, it has been found that the tan δ values are strongly dependent upon shear stress. Therefore, such measurements have to be carried out with high precision, since small variations in the in phase and out of phase viscosity values will have a strong influence upon the tan δ values obtained. The Anton Paar GmbH Physica MCR 501 with concentric cylinders enables such high precision measurements to be carried out.

The tan δ, as used in disclosing the present invention, is the tan δ of the liquid composition at the coating head i.e. the tan δ of the liquid composition during the slot extrusion coating process. It has been found that subjection of liquid compositions to shear stress such as during mixing, pumping and filtration results in significant increases in tan δ values. Therefore, tan δ values measured on liquid composition samples in storage vessels are significantly lower than the tan δ values pertaining in the liquid composition during the slot extrusion coating process, due to the shear stress experienced by the liquid composition during transport to the coating head.

According to a twentieth embodiment of the method for slot extrusion coating, according to the present invention, the tan δ measured by oscillatory dynamic measurements at 1 Hz, the coating temperature and a shear stress of 250 Pa is measured with a concentric cylinder configuration.

According to an eighteenth embodiment of the method for selecting a liquid composition for slot extrusion coating, according to the present invention, the tan δ measured by oscillatory dynamic measurements at 1 Hz, the coating temperature and a shear stress of 250 Pa is measured with a concentric cylinder configuration.

### Liquid Composition

Aspects of the present invention have been realized by a method for slot extrusion coating a liquid composition at a coating temperature and a coating speed at or above 40 m/min, the liquid composition having a viscosity at the coating temperature of at least 500 mPa·s at a shear rate of 100 s⁻¹, comprising the steps of: (i) selecting the liquid composition having a tan δ of less than 1000 measured by oscillatory dynamic viscosity measurements at 1 Hz, the coating temperature and a shear stress of 250 Pa under conditions in which there is effectively no variation in shear stress within the liquid composition during the measurements, the liquid composition being selected from liquid compositions each comprising at least one binder and a liquid carrier medium; and (ii) slot extrusion coating the composition via a slot onto a web support with a bead vacuum at the coating temperature and the coating speed. Typical bead vacuums used were in the range 0.5 to 4.75 kPa, the highest bead vacuum realizable in the coating configuration used.

The liquid compositions from which the liquid composition is selected for slot extrusion coating, according to the present invention, may be a solution i.e. all the ingredients are dissolved in the carrier medium or may be a dispersion i.e. at least one ingredient is at least partially insoluble in the liquid carrier medium. The liquid carrier medium used in the liquid composition used in the method for slot extrusion coating, according to the present invention, comprises one or more liquids and may be aqueous or non-aqueous.

The liquid compositions from which the liquid composition is selected may comprise the same or different binders. The at least one binder may be completely or partially dissolved in the liquid. The elasticity of a liquid composition can be influenced by the choice of the binder e.g. the chain length, the molecular weight distribution, the degree of crosslinking and the nature of the monomer units in the chain. For example, broadening the molecular weight distribution of a polymer, i.e. increasing its polydispersity, has been found to increase the elasticity of a concentrated solution of a polymer and liquid compositions containing other ingredients made therefrom. These monomer units may be bulky, may bond non-covalently more or less strongly to one another e.g. by hydrogen bonding, ionic bonding as in ionomers, by electron donor-electron acceptor interaction between pendant groups, by London forces and by Van der Waals forces.

Elasticity can also be realized by adding elasticity-enhancing additives, which bond non-covalently more or less strongly with the monomer units of the binder e.g. by hydrogen bonding, ionic bonding, electron donor-electron acceptor interaction with pendant monomer groups, London forces and Van der Waals forces, or which induce physical cross-linking such as realized with fine particles, such as silica, alumina, CaCO₃, BaSO₄ and substantially light-insensitive organic silver salts, or with particles with particular morphologies, such as flake-shaped particles e.g. clay and kaolin. However, the loss in elasticity due to physical crosslinking with fine particles upon subjection to shear treatment is less reversible than the loss in elasticity upon subjection to shear treatment in the absence of fine particles. Even the shear involved in transport from the storage vessel to the coating head can result in irreversible loss in elasticity.

### Substantially Light-Insensitive Thermographic Recording Materials

A substantially light-insensitive thermographic recording material comprises a thermosensitive element and a support.

### Thermosensitive Elements

The term thermosensitive element as used herein is that element which contains all the ingredients which contribute to image formation e.g. leuco dyes, acids, substantially light-insensitive organic silver salts and reducing agents. According to a preferred embodiment of the present invention, the thermosensitive element contains one or more substantially light-insensitive organic silver salts, one or more reducing agents therefor in thermal working relationship therewith and a binder. The element may comprise a layer system in which the above-mentioned ingredients may be dispersed in different layers, with the proviso that the substantially light-insensitive organic silver salts are in reactive association with the reducing agents i.e. during the thermal development process the reducing agent must be present in such a way that it is able to diffuse to the particles of substantially light-insensitive organic silver salt so that reduction to silver can occur. Such materials include the possibility of one or more substantially light-insensitive organic silver salts and/or one of more organic reducing agents therefor being encapsulated in heat-responsive microcapsules, such as disclosed in EP-A 0 736 799 herein incorporated by reference.

### Toning Agent

A thermosensitive element prepared using the method for slot extrusion coating may further comprise at least one toning agent preferably selected from the group consisting of phthalazinone, phthalazinone derivatives, pyridazone, pyridazone derivatives, benzoxazine dione, benzoxazine dione derivatives, naphthoxazine dione and naphthoxazine dione derivatives.

Particularly suitable benzoxazine dione toning agents are benzo[e][1,3]oxazine-2,4-dione, 7-(ethylcarbonato)-benzo[e][1,3]-oxazine-2,4-dione, 7-methoxy-benzo[e][1,3]oxazine-2,4-dione and 7-methyl-benzo[e][1,3]oxazine-2,4-dione.

### Organic Silver Salt

The organic silver salts optionally comprised in the coating prepared according to the method for slot extrusion coating, according to the present invention, are preferably not double organic salts containing a silver cation associated with a second cation e.g. magnesium or iron ions and are preferably silver salts of aliphatic carboxylic acids known as fatty acids, wherein the aliphatic carbon chain has preferably at least 12 C-atoms, e.g. silver laurate, silver palmitate, silver stearate, silver hydroxystearate, silver oleate and silver behenate, with silver behenate being particularly preferred. Such silver salts are also called “silver soaps”.

### Reducing Agents

The organic reducing agent optionally comprised in the coating prepared according to the method for slot extrusion coating, according to the present invention, is preferably an organic compound containing at least one active hydrogen atom linked to O, N or C, such as is the case with, aromatic di- and tri-hydroxy compounds. 1,2-dihydroxy-benzene derivatives, such as catechol, 3-(3,4-dihydroxyphenyl) propionic acid, 1,2-dihydroxybenzoic acid, gallic acid and esters e.g. methyl gallate, ethyl gallate, propyl gallate and 3,4-dihydroxy-benzoic acid esters are preferred, with those described in EP-A 0 692 733, EP-A 0 903 625, EP-A 1 245 403 and EP-A 1 245 404 herein incorporated by reference being particularly preferred e.g. ethyl 3,4-dihydroxybenzoate, 3,4-dihydroxybenzophenone and derivatives thereof, and 3,4-dihydroxy-benzonitrile.

### Binder

Aspects of the present invention have been realized by a method for slot extrusion coating a liquid composition at a coating temperature and a coating speed at or above 40 m/min, the liquid composition having a viscosity at the coating temperature of at least 500 mPa·s at a shear rate of 100 s⁻¹, comprising the steps of: (i) selecting the liquid composition for slot extrusion coating having a tan δ of less than 1000 measured by oscillatory dynamic viscosity measurements at 1 Hz, the coating temperature and a shear stress of 250 Pa under conditions in which there is effectively no variation in shear stress within the liquid composition during the measurements, the liquid composition being selected from liquid compositions each comprising at least one binder and a liquid carrier medium; and (ii) slot extrusion coating the composition via a slot onto a web support with a bead vacuum at the coating temperature and the coating speed.

Aspects of the present invention have also been realized by a method for selecting a liquid composition for slot extrusion coating at a coating temperature and a coating speed at or above 40 m/min, the liquid composition having a viscosity at the coating temperature of at least 500 mPa·s at a shear rate of 100 s⁻¹, comprising the step of: (i) selecting the liquid composition for slot extrusion coating having a tan δ of less than 1000 measured by oscillatory dynamic viscosity measurements at 1 Hz, the coating temperature and a shear stress of 250 Pa under conditions in which there is effectively no variation in shear stress within the liquid composition during the measurements, the composition being selected from liquid compositions each comprising at least one binder and a liquid carrier medium.

The binder used in the present invention may be all kinds of natural, modified natural or synthetic resins or mixtures of such resins and may be soluble or at least partially insoluble in the liquid carrier medium.

Binders are preferred whose solutions or dispersions exhibit viscoelastic properties, but excessive viscoelasticity can causing coating defects such as ribbing. Adding small quantities of high molecular weight polyacrylamide to viscoelastic aqueous solutions can reduce their elasticity. Binders are also preferred with high dispersities as defined by the ratio of M_{w} to Mₙ, with dispersities greater than 3.5 being preferred. An indicator of the suitability of a binder for the method for slot extrusion coating according to the present invention is its viscosity at concentrations of 20 or 30% by weight in the liquid carrier medium.

Examples of suitable polymers include, but are not restricted to: cellulose derivatives, starch ethers, galactomannan, polymers derived from α,β-ethylenically unsaturated compounds such as polyvinyl chloride, after-chlorinated polyvinyl chloride, copolymers of vinyl chloride and vinylidene chloride, copolymers of vinyl chloride and vinyl acetate, polyvinyl acetate and partially hydrolyzed polyvinyl acetate, polyvinyl alcohol, polyvinyl acetals that are made from polyvinyl alcohol as starting material in which only a part of the repeating vinyl alcohol units has reacted with at least one aldehyde, preferably polyvinyl butyral, polyvinyl aceto-acetal or a copolymer comprising vinyl butyral and vinyl aceto-acetal units, copolymers of acrylonitrile and acrylamide, polyacrylates, polymethacrylates, polystyrene and polyethylene or mixtures thereof. These binders are also suitable for homogeneously dispersing at least one organic silver salt in either the aqueous or a non-aqueous liquid carrier medium, used in the present invention.

In the case of copolymers comprising vinyl aceto-acetal and vinyl butyral units, viscosities at a concentration of 20% by weight in the carrier medium greater than 800 mPa·s at the coating temperature and a shear rate of 100 s⁻¹ are preferred. In the case of polyvinyl butyrals viscosities at a concentration of 30% by weight in the carrier medium greater than 4.0 Pa·s at the coating temperature and a shear rate of 10 s⁻¹ are preferred.

The binder may be a polymer latex. Preferred polymer latexes include polyester, polyurethane and acrylic ester copolymers, which facilitate particle coalescence in the film-forming process.

Suitable water-soluble film-forming binders include, but are not restricted to: polyvinyl alcohol, polyacrylamide, polymethacrylamide, polyacrylic acid, polymethacrylic acid, polyvinylpyrrolidone, polyethyleneglycol, proteinaceous binders, polysaccharides and water-soluble cellulose derivatives.

Binders whose concentrated solutions exhibit a viscosity at the coating temperature of at least 500 mPa·s at a shear rate of 100 s⁻¹, and a tan δ of less than 1000, measured by oscillatory dynamic viscosity measurements at 1 Hz, the coating temperature and a shear stress of 250 Pa under conditions in which there is effectively no variation in shear stress within the liquid composition during the measurements, include polyvinyl acetals that are made from polyvinyl alcohol as starting material in which only a part of the repeating vinyl alcohol units have reacted with at least one aldehyde, polyacrylates, polymethacrylates, polyacrylonitrile, styrene-acrylonitrile copolymers, polysaccharides, polyethylene oxides or mixtures thereof.

Polysaccharides, certain polyacrylates and poly(hexano-6-lactone), poly(lactide)-poly(ethylene oxide)-poly(lactide)(PLA-PEO-PLA) triblock copolymers, poly(2-vinylpyridine) and poly(isoprene) with short hydrophilic endblocks of polyethylene oxide are suitable for use with aqueous liquid carrier media. Suitable polysaccharides include cellulose, cellulose derivatives, e.g. carboxymethyl cellulose, guar gum and xanthan gum e.g. BIOSAN® S from Hercules Inc., USA and Kelzan® T from MERCK & Co., Kelco Division, USA. Suitable polyacrylates for use with aqueous liquid carrier media include high molecular weight homo- and copolymers of acrylic acid crosslinked with a polyalkenyl polyether, such as the CARBOPOL® resins of B. F. Goodrich e.g. CARBOPOL® ETD 2623.

The binder to organic silver salt weight ratio in thermosensitive elements optionally produced by the method for slot extrusion coating, according to the present invention, is preferably in the range of 0.2 to 7, and the thickness of the thermosensitive element is preferably in the range of 5 to 50 μm. Binders for the thermosensitive element optionally produced by the method for slot extrusion coating, according to the present invention, preferably do not contain additives, such as certain antioxidants (e.g. 2,6-di-tert-butyl-4-methylphenol), or impurities which adversely affect the thermographic properties of the thermographic recording materials in which they are used.

### Stabilizers

The stabilizer optionally comprised in the coating prepared according to the method for slot extrusion coating, according to the present invention, is preferably at least one stabilizer selected from the group consisting of benzotriazole; substituted benzotriazoles; aromatic polycarboxylic acid, such as ortho-phthalic acid, 3-nitro-phthalic acid, tetrachlorophthalic acid, mellitic acid, pyromellitic acid and trimellitic acid and anhydrides thereof; and compounds with two or more groups represented by formula (I): 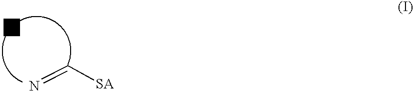
where Q comprises the necessary atoms to form a 5- or 6-membered unsaturated heterocyclic ring, A is hydrogen, a counterion to compensate the negative charge of the thiolate group or two or more A groups provide a linking group between the two or more groups represented by formula (I).

The thermosensitive element optionally produced by the method for slot extrusion coating, according to the present invention, preferably further contains at least one optionally substituted aliphatic or carbocyclic polycarboxylic acid and/or anhydride thereof in a molar percentage of at least 15 with respect to all the organic silver salt(s) present and in thermal working relationship therewith. The polycarboxylic acid may be used in anhydride form or partially esterified on the condition that at least two free carboxylic acids remain or are available during the heat recording step.

### Photosensitive Silver Halide

Photosensitive silver halide is optionally comprised in the coating prepared according to the method for slot extrusion coating and may be spectrally sensitized with spectrally sensitizing cyanine or merocyanine dyes and/or chemically sensitized.

The thermosensitive element optionally produced by the method for slot extrusion coating, according to the present invention, may further comprises photosensitive silver halide, thereby rendering the thermographic material photothermographic.

The photosensitive silver halide used in the thermosensitive element may be employed in a range of 0.1 to 100 mol percent; preferably, from 0.2 to 80 mol percent; particularly preferably from 0.3 to 50 mol percent; especially preferably from 0.5 to 35 mol %; and especially from 1 to 12 mol % of substantially light-insensitive organic silver salt.

The silver halide may be any photosensitive silver halide such as silver bromide, silver iodide, silver chloride, silver bromoiodide, silver chlorobromoiodide, silver chlorobromide etc. The silver halide may be in any form which is photosensitive including, but not limited to, cubic, orthorhombic, tabular, tetrahedral, octagonal etc. and may have epitaxial growth of crystals thereon.

Surfactants and Dispersants

At least one surfactant and/or dispersant, which aid the dispersion of ingredients which are insoluble in the particular dispersion medium, is optionally comprised in the coating prepared according to the method for slot extrusion coating. These surfactants may be anionic, non-ionic or cationic. Suitable dispersants are natural polymeric substances, synthetic polymeric substances and finely divided powders, e.g. finely divided non-metallic inorganic powders such as silica.

### Support

The support on which the liquid composition is coated may be transparent or translucent. It is preferably a thin flexible transparent resin film, e.g. made of a cellulose ester, e.g. cellulose triacetate, polypropylene, polycarbonate or polyester, e.g. polyethylene terephthalate. The support may be in ribbon or web form and subbed if needs be to improve the adherence to the thereon coated thermosensitive element. The support may be dyed or pigmented to provide a transparent coloured background for the image.

### Protective Layer

The coating prepared by a method for slot extrusion coating, according to the present invention, may be provided with a protective layer, which may be a slipping layer.

In the case of the coating being a thermosensitive element, this protects the thermosensitive element from atmospheric humidity and from surface damage by scratching etc. and prevents direct contact of printheads or heat sources with the recording layers. Protective layers for thermosensitive elements which come into contact with and have to be transported past a heat source under pressure, have to exhibit resistance to local deformation and good slipping characteristics during transport past the heat source during heating.

A slipping layer, being the outermost layer, may comprise a dissolved lubricating material and/or particulate material, e.g. talc particles, optionally protruding from the outermost layer. Examples of suitable lubricating materials are a surface active agent, a liquid lubricant, a solid lubricant or mixtures thereof, with or without a polymeric binder.

### Thermographic Processing

Thermographic imaging with a thermographic recording material is carried out by the image-wise application of heat either in analogue fashion by direct exposure through an image or by reflection from an image, or in digital fashion pixel by pixel either by using an infra-red heat source, for example with a Nd-YAG laser or other infra-red laser, with a substantially light-insensitive thermographic material preferably containing an infra-red absorbing compound, or by direct thermal imaging with a thermal head.

### Photothermographic Printing

Photothermographic recording materials, according to the present invention, may be exposed with radiation of wavelength between an X-ray wavelength and a 5 microns wavelength with the image either being obtained by pixel-wise exposure with a finely focused light source, such as a CRT light source; a UV, visible or IR wavelength laser, such as a Violet-laser, a He/Ne-laser or an IR-laser diode, e.g. emitting at 400 nm, 630 nm, 650 nm, 780 nm, 830 nm or 850 nm; or a light emitting diode, for example one emitting at 659 nm; or by direct exposure to the object itself or an image therefrom with appropriate illumination e.g. with UV, visible or IR light.

For the thermal development of image-wise exposed photothermographic recording materials, according to the present invention, any sort of heat source can be used that enables the recording materials to be uniformly heated to the development temperature in a time acceptable for the application concerned e.g. contact heating, radiative heating, microwave heating etc.

### INDUSTRIAL APPLICATION

The method for slot extrusion coating, according to the present invention, may be used to coat any layers. A particular application is the coating of the layer or layers comprising the thermosensitive element of a thermographic recording material, which can be used in medical and graphics applications.

The invention is illustrated hereinafter by way of COMPARATIVE EXAMPLES and INVENTION EXAMPLES. The percentages and ratios given in these examples are by weight unless otherwise indicated.

Subbing layer Nr. 01 on the emulsion side of the support had the composition:

| | |
|---|---|
| copolymer of 88% vinylidene chloride, | 79.1 mg/m² |
| 10% methyl acrylate and 2% itaconic acid | |
| Kieselsol ® 100F, a colloidal silica | 18.6 mg/m² |
| from BAYER | |
| Mersolat ® H, a surfactant from BAYER | 0.4 mg/m² |
| Ultravon ® W, a surfactant from CIBA-GEIGY | 1.9 mg/m² |

Ingredients in the thermosensitive element in addition to the above-mentioned ingredients:

AgBeh=silver behenate

Oil=BAYSILON, a silicone oil from BAYER;

VL=DESMODUR VL, a 4,4′-diisocyanatodiphenylmethane from BAYER;

Binders:

| | Vinyl | | | | | | | |
|---|---|---|---|---|---|---|---|---|
| | aceto- | vinyl | vinyl | vinyl | | | | |
| Binder | acetal | butyral | alcohol | acetate | Tg | | | |
| No. | [mol %/wt %] | [mol %/wt %] | [mol %/wt %] | [mol %/wt %] | [° C.] | Mw × 10⁻³ | Mn × 10⁻³ | |
| | | | | | | | | viscosity of 30 wt % |
| | | | | | | | | 2-butanone solution at |
| | | | | | | | | 10 s⁻¹ & 20° C. [Pa · s] |
| 1 | 0/0 | 66/85 | 32/13 | 2.2/1.7 | 62 | 122 | 36 | 4.84 |
| 2 | 0/0 | 62/83 | 36/15 | 2.1/1.7 | | 115 | 27.3 | 4.61 |
| 18 | 0/0 | 64/84.4 | 34/13.9 | 2.1/1.7 | | | | 4.09 |
| 19 | 0/0 | 65/85 | 33/13 | 2.0/1.6 | | | | 3.86 |
| 20 | 0/0 | 63/84 | 35/14 | 2.0/1.6 | | 132.0 | 32.8 | 3.89 |
| 21 | 0/0 | 66/85 | 33/13 | 2.0/1.6 | | | | 3.50 |
| 22 | 0/0 | 64/84 | 34/14 | 2.2/1.8 | | | | 3.715 |
| 23 | 0/0 | 63/84 | 35/14 | 2.2/1.8 | | | | 3.59 |
| | | | | | | | | viscosity of 20 wt % |
| | | | | | | | | 2-butanone solution at |
| | | | | | | | | 100 s⁻¹ & 20° C. [Pa · s] |
| 3 | 42/47 | 28/39 | 30/13 | 1.2/1.0 | 88.8 | 144.3 | 49.6 | 2.21 (30 s⁻¹); |
| | | | | | | | | 1.71 |
| 4 | 40/47 | 25/37 | 34/15 | 1.6/1.5 | 90 | 136.8 | 44.3 | 2.07 (30 s⁻¹); |
| | | | | | | | | 1.79 |
| 5 | 34/46 | 25/37 | 34/15 | 1.6/1.4 | 87.1 | 127.0 | 40.4 | 1.45 (30 s⁻¹); |
| | | | | | | | | 1.34 |
| 6 | 37/44 | 26/38 | 36/17 | 2/2 | 89.6 | 132 | 44.2 | 1.43 (30 s⁻¹); |
| | | | | | | | | 1.33 |
| 7 | 39/46 | 25/37 | 34/16 | 1.6/1.5 | 91 | 125.5 | 42.9 | 1.51 (30 s⁻¹); |
| | | | | | | | | 1.19 |
| 8 | 40/47 | 25/36 | 34/16 | 1.6/1.4 | 88 | 127.1 | 41.9 | 1.49 (30 s⁻¹); |
| | | | | | | | | 1.36 |
| 9 | 39/46 | 27/39 | 33/15 | <1/<1 | 82 | 98.1 | 30.2 | very low |
| | | | | | | | | 6.3 (30% & 10 s⁻¹) |
| 10 | 38/44 | 26/38 | 33/15 | 3/3 | 88 | 155.6 | 47.4 | 4.80 |
| 11 | 38/44 | 27/39 | 33/15 | 2/2 | 89.6 | 128.5 | 42.2 | 1.60 (30 s⁻¹) |
| 12 | 36/40 | 33/46 | 29/12 | 2/2 | 85.6 | 140.8 | 46.9 | 1.55 (30 s⁻¹) |
| 13 | 50/56 | 23/32 | 26/11 | 1/1 | 93.8 | 127.4 | 45.9 | 2.00 (30 s⁻¹) |
| 14 | 40/45 | 28/40 | 29/12 | 3/3 | 89.2 | 122.7 | 44.5 | 1.35 (30 s⁻¹); |
| | | | | | | | | 1.60 |
| 15 | 38/44 | 27/39 | 32/14 | 3/2 | 89.4 | 148.8 | 50.4 | 2.66 (30 s⁻¹); |
| | | | | | | | | 3.00 |
| 16 | 39/45 | 27/39 | 33/15 | 2/1 | 89.1 | 157.1 | 47.8 | 2.90 (30 s⁻¹); |
| | | | | | | | | 3.20 |
| 17 | 38/44 | 27/39 | 33/15 | 2/2 | 90 | 116.1 | 43.0 | 1.05 (30 s⁻¹); |
| | | | | | | | | 1.10 |

Reducing Agents:

R01=3,4-dihydroxybenzonitrile;

R02=3,4-dihydroxybenzophenone;

R03=3,4-dihydroxybenzoic acid ethyl ester

Toning Agents:

| | |
|---|---|
| T01 | 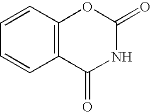 |
| | benzo[e][1,3]oxazine-2,4-dione |
| T02 | 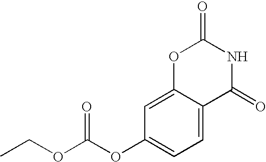 |
| | 7-(ethylcarbonato)-benzo[e][1,3]oxazine-2,4-dione |
| T03 | 7-methyl-benzo[e][1,3]oxazine-2,4-dione |

Stabilizers:

S01=glutaric acid

S02=tetrachlorophthalic acid anhydride

S03=benzotriazole

S04=

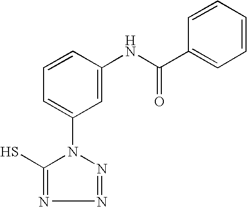

### EXAMPLE 1

A dispersion of silver behenate was prepared as follows: first a predispersion of silver behenate in 2-butanone was prepared containing 34.9% by weight of silver behenate and 5.2% by weight of binder 1 using a slightly modified KOWLESS-stirrer, which is further diluted with 2-butanone to 26.2% by weight of silver behenate prior to being subjected to pearl milling (bead diameter=0.65 mm) for 9 minutes in a circulating system pumped at 300 rpm followed by pearl milling for 26 minutes in a circulating system pumped at 500 rpm. A solution of the binder 1 in 2-butanone was then added resulting in a dispersion containing 20.4% by weight of silver behenate and 5.5% by weight of binder 1, which was pumped into a production vessel in which further binder solution was added followed by 1 minute pearl milling in a circulating system and then still further binder solution is added again followed by 1 minute pearl milling in a circulating system resulting in a stable silver behenate dispersion containing 13.3% by weight of silver behenate and 7.6% by weight binder 1.

A 2-butanone solution containing 2.204% by weight of binder 1, 0.107% by weight of S04, 0.107% by weight of S03, 1.33% by weight of R01, 2.11% by weight of R02, 0.64% by weight of S01, 0.308% by weight of S02, 0.477% by weight of T03, 0.064% by weight of Baysilon and 21.287% by weight of the binder given in Table 1 below was then prepared and mixed with stirring with the silver behenate dispersion to obtain the final dispersion to which was added just prior to coating a 2-butanone solution of Desmodur® VL giving a final solids concentration of 25.05% by weight.

In phase and 90° out of phase viscosity measurements were extracted from complex viscosity measurements carried out with a oscillatory rotary viscometer, the Anton Paar Physica MCR 501, with a CC27 concentric cylinder configuration with a TEZ 150P-C temperature control system at a shear stress of 250 Pa, on samples taken from the storage vessel at an oscillatory frequency of 1 Hz and 20° C. giving η′ and η″, the dynamic viscosity and storage viscosity respectively. G″ and G′ are related to the two dynamic viscosity coefficients η′ and η″, the dynamic viscosity and storage viscosity respectively. Since G″ and G′ are related to the two dynamic viscosity coefficients η′ and η″ via: G″=ωη′ and G′=ωη″, tan δ, being the ratio of G″ to G′, could be calculated. Values of tan δ above 1500 measured with the MCR 501 are unreliable and irreproducible, due to insufficient precision in the G′ value.

The CC 27 configuration is a coaxial cylinder measuring system according to ISO 3219 with a coaxial cylinder 26.66 mm in diameter, which is mounted in a cup 28.92 mm in diameter and operates in the oscillatory frequency range of 0.0001 Hz to 100 Hz.

The results of these oscillatory rotational viscometer measurements are summarized in Table 1 below.

TABLE 1

| | | | tan δ at 250 Pa, 1 Hz and 20° C. | | |
|---|---|---|---|---|---|
| | | | | after 90 s shear | |
| | | Viscosity | | stress at 1500 s⁻¹* | |
| Disper- | | at 100 s⁻¹ | | immediately | 15 min |
| sion | Binder | & 20° C. | no pre- | after | after |
| No. | No. | [Pa · s] | shear | shear | shear |
| 1.1 | 1 + 3 | 1.43 | 64 | 107 | 89 |
| 1.2 | 1 + 4 | 1.33 | 79 | 136 | 126 |
| 1.3 | 1 + 5 | 1.17 | 121 | | |
| 1.4 | 1 + 6 | 1.23 | 95 | | |
| 1.5 | 1 + 7 | 1.15 | 119 | | |
| 1.6 | 1 + 8 | 1.15 | 130 | | |
| 1.7 | 1 + 9 | 0.36 | >1000 | | |
| 1.8 | 1 + 10 | 1.73 | 55 | | |
| 1.9 | 1 + 11 | 1.12 | 218 | | |
| 1.10 | 1 + 12 | 1.19 | 134 | | |
| 1.11 | 1 + 13 | 1.22 | 112 | | |
| 1.12 | 1 + 14 | 0.95 | 380 | | |
| 1.13 | 1 + 15 | 1.46 | 91 | | |
| 1.14 | 1 + 16 | 1.58 | 83 | | |
| 1.15 | 1 + 17 | 0.87 | >1000 | | |

*simulating transport to coating head

Table 1 provides data for liquid compositions with a wide range of binders, which fulfil the criteria for providing a significant window of coatability in slot extrusion coating at coating speeds at or above 40 m/min i.e. a viscosity at 20° and 100 s⁻¹ above 500 mPa·s and a tan δ value measured at a shear stress of 250 Pa, 1 Hz and 20° C. of less than 1000. However, the tan δ values were measured on samples taken from a storage vessel and not from a slot extrusion coating head and as discussed above the shear stress involved during the transport process to the slot extrusion coating head results in a significant increase in the tan δ value.

Experiments were therefore carried out in which several of these liquid compositions were subjected to shear stress to simulate the shear stress involved during the transport process to the slot extrusion coating head. 90 s subjection of dispersions 1.1 and 1.2 to the shear stress of 1500 s⁻¹ approximately doubled the tan δ values from 64 and 79 to 107 and 136 respectively. Moreover, it was found that this increase in tan δ was reduced by 42% and 18% respectively over a period of 15 minutes.

### EXAMPLE 2

The composition of the layers coated with Dispersion types 1, 2 and 3 is given in Table 2 below together with the solids concentration of the 2-butanone dispersion from which the layers were coated.

TABLE 2

| | | Dispersion | Dispersion | Dispersion |
|---|---|---|---|---|
| | | type 1 | type 2 | type 3 |
| AgBeh | [g/m²] | 4.155 | 4.139 | 3.738 |
| Binder No. 1 | [g/m²] | 16.60 | 16.55 | 3.177 |
| Main binder | [g/m²] | — | — | 9.904 |
| T01 | [g/m²] | 0.227 | — | — |
| | [mol % vs AgBeh] | 15 | — | — |
| T02 | [g/m²] | 0.117 | — | — |
| | [mol % vs AgBeh] | 5 | — | — |
| T03 | [g/m²] | — | 0.246 | 0.222 |
| | [mol % vs AgBeh] | — | 15 | 15 |
| R01 | [g/m²] | 0.063 | 0.437 | 0.621 |
| | [mol % vs AgBeh] | 5 | 35 | 55 |
| R02 | [g/m²] | — | 0.892 | 0.984 |
| | [mol % vs AgBeh] | — | 45 | 55 |
| R03 | [g/m²] | 0.838 | — | — |
| | [mol % vs AgBeh] | 49.48 | — | — |
| S01 | [g/m²] | 0.288 | 0.285 | 0.298 |
| | [mol % vs AgBeh] | 23 | 26 | 27 |
| S02 | [g/m²] | 0.131 | 0.130 | 0.143 |
| | [mol % vs AgBeh] | 4.97 | 4.91 | 6 |
| S03 | [g] | 0.109 | 0.053 | 0.050 |
| | [mol % vs AgBeh] | 9.83 | 4.84 | 5 |
| S04 | [g/m²] | — | 0.138 | 0.050 |
| | [mol % vs AgBeh] | — | 1 | 2 |
| Baysilon | [g/m²] | — | 0.036 | 0.030 |
| VL | [g] | — | — | 0.185 |
| total laydown | [g/m²] | 22.51 | 22.906 | 19.401 |
| % by wt solids | | 27.32 | 28.98 | 25.05 |

However, the viscoelastic properties of the dispersions are dependent upon how the dispersions are prepared and what happens to the dispersion prior to their being slot extrusion coated.

Dispersion type 1 was prepared as follows: first a predispersion of silver behenate in 2-butanone was prepared containing 34.8% by weight of silver behenate and 5.2% by weight of binder using a slightly modified KOWLESS-stirrer, which is further diluted with 2-butanone to 26.1% by weight of silver behenate prior to being subjected to pearl milling (bead diameter=0.65 mm) for 9 minutes in a circulating system pumped at 300 rpm followed by pearl milling for 26 minutes in a circulating system pumped at 500 rpm. A solution of the binder in 2-butanone was then added resulting in a dispersion containing 20.5% by weight of silver behenate and 5.5% by weight of binder, which was pumped into a production vessel in which further binder solution is added followed by 1 minute pearl milling in a circulating system and then still further binder solution is added again followed by 1 minute pearl milling in a circulating system resulting in a stable silver behenate dispersion containing 13.0% by weight of silver behenate and 7.66% by weight binder. A 2-butanone solution containing 30.6% by weight of binder and 0.25% by weight of benzotriazole was then added to the silver behenate dispersion to produce a silver behenate dispersion containing 20.9% by weight of binder, 5.5% by weight of silver behenate and 0.14% by weight of benztriazole. The Baysilon, T01, T02 and glutaric acid were then added with stirring followed by a 2-butanone solution containing the remaining binder, the R01, the R03 and the S02 to obtain the final dispersion with a solids concentration of 27.32% by weight. Dispersion type 1 was used in Dispersion No. 2.1, 2.6, 2.7. 2.9, 2.10, 2.15 to 2.18 and 2.21 with the binder indicated in Table 7 below. The additional indication “+IKA” means that the dispersion was additionally subjected to shear stress by mixing.

Dispersion type 2 was prepared as follows: first a predispersion of silver behenate in 2-butanone was prepared containing 34.8% by weight of silver behenate and 5.2% by weight of binder using a slightly modified KOWLESS-stirrer, which is further diluted with 2-butanone to 26.1% by weight of silver behenate prior to being subjected to pearl milling (bead diameter=0.65 mm) for 9 minutes in a circulating system pumped at 300 rpm followed by pearl milling for 26 minutes in a circulating system pumped at 500 rpm. A solution of the binder in 2-butanone was then added resulting in a dispersion containing 20.4% by weight of silver behenate and 5.5% by weight of binder, which was pumped into a production vessel in which further binder solution is added followed by 1 minute pearl milling in a circulating system and then still further binder solution is added again followed by 1 minute pearl milling in a circulating system resulting in a stable silver behenate dispersion containing 13.2% by weight of silver behenate and 7.61% by weight binder. A 2-butanone solution containing 33.3% by weight of binder, 0.13% by weight of benzotriazole, 0.348% by weight of S04 and 0.622% by weight of T03 was then added to the silver behenate dispersion to produce a silver behenate dispersion containing 21.95% by weight of binder, 5.8% by weight of silver behenate, 0.35& by weight of T03, 0.072% by weight of S03 and 0.09% by weight of S04. A 2-butanone solution containing the remaining binder, the R01, the R02, the S01 and the S02 was then added with stirring to obtain the final dispersion with a solids concentration of 28.98% by weight. Dispersion type 2 was used in Dispersion No. 2.8, 2.11 to 2.14, 2.19 and 2.20 with the binder indicated in Table 3 below. The additional indication “+IKA” means that the dispersion was additionally subjected to shear stress by mixing.

Dispersion type 3 was prepared as the dispersions in EXAMPLE 3, except that the main binder in Table 1 was replaced with the main binder indicated for Dispersion No. 2.2 to 2.5 in Table 3 below.

In phase and 90° out of phase viscosity measurements were extracted from complex viscosity measurements carried out with a oscillatory rotary viscometer, the Anton Paar Physica MCR 501, with a CC27 concentric cylinder configuration with a TEZ 150P-C temperature control system at a shear stress of 250 Pa, on samples taken from the storage vessel at an oscillatory frequency of 1 Hz and 20° C. giving η′ and η″, the dynamic viscosity and storage viscosity respectively. G″ and G∝0 are related to the two dynamic viscosity coefficients η′ and η″, the dynamic viscosity and storage viscosity respectively. Since G″ and G′ are related to the two dynamic viscosity coefficients η′ and η″ via: G″=ωη′ and G′=ωη″, tan δ, being the ratio of G″ to G′, could be calculated.

Tan δ values at a shear stress of 250 Pa, 1 Hz and 20° C. were obtained from oscillatory rotary viscometer measurements carried out immediately after sampling on dispersions 2.1 to 2.21 immediately after being produced, after standing for 24 hours in a holding tank and at the coating head after the dispersion has stood in the holding tank for 24 hours. Values of tan δ above 1500 measured with the MCR 501 are unreliable and irreproducible, due to insufficient precision in the G′ value. The results are summarized in Table 3 below.

The window of coatability, ΔP, was determined empirically at coating speeds of 80 m/min and 90 m/min by varying the applied bead vacuum, P, and determining Pₘᵢₙ as the lowest bead vacuum at which air entrainment was not visually observed in the coating and Pₘₐₓ as the highest bead vacuum at which there was no bead break up resulting in “rivulets”. The window of coatability, ΔP, is Pₘₐₓ-Pₘᵢₙ. The results are summarized in Table 3 above.

TABLE 3

| | | | | | Tan δ of dispersion at shear | | | | |
|---|---|---|---|---|---|---|---|---|---|
| | | | Degree of | | stress of 250 Pa, 1 Hz & 20° C. | | | | |
| | | | concentration | viscosity | | after | at coating | window of coatability | |
| Disper- | | Disper- | of base | at 20° C. & | fresh in | 24 h in | head after | [ΔP in kPa] at | |
| sion | Binder | sion | dispersion | 100 s⁻¹ | holding | holding | 24 h in | coating speed of | |
| No. | No. | type | [%] | [Pa · s] | tank | tank | holding tank | 80 m/min | 90 m/min |
| 2.1 | 2 | 1 | 0 | 839 | — | 40 | 107 | >3.5# | — |
| 2.2 | 3 | 3 | 0 | 1650 | — | — | 100 | >2.75 | >2.9 |
| 2.3 | 4 | 3 | 0 | 1140 | — | 85 | 180 | 2.2 | — |
| 2.4 | 5 | 3 | 0 | 1100 | — | 100 | 230 | 1.8 | — |
| 2.5 | 6 | 3 | 0 | 950 | | 135 | 520 | 0.9 | — |
| 2.6 | 18 | 1 | 0 | 1100 | 40; 50 | — | 150 | — | — |
| 2.7 | 18 | 1 | 6 | 1440 | 30; 40 | — | 100 | 2.35 | >2.5 |
| 2.8 | 18 | 2 | 5 | 1320 | 60 | — | 150 | — | >2.0 |
| 2.9 | 19 | 1 | 6 | >1000 | 38 | 37 | — | — | — |
| 2.10 | 19 | 1 + | 6 | 1000 | 45 | 51 | 350 | — | 1.5 |
| | | IKA | | | | | | | |
| 2.11 | 19 | 2 | 5 | >1020 | 66 | 64 | — | — | |
| 2.12 | 19 | 2 + | 5 | 1020 | 84 | 78 | 350 | — | 1.0 |
| | | IKA | | | | | | | |
| 2.13 | 20 | 2 | 5 | >1050 | — | 60 | — | — | — |
| 2.14 | 20 | 2 + | 5 | 1050 | — | 77 | 325 | — | 0.9 |
| | | IKA | | | | | | | |
| 2.15 | 21 | 1 | 0 | 817 | — | 90; 115 | 450 | 1.25 | 0.9 |
| 2.16 | 21 | 1 + | 0 | 729 | — | 180 | >1000 | 0.9 | 0.4 |
| | | IKA | | | | | | | |
| 2.17 | 22 | 1 | 0 | >980 | 60; 90 | 70; 120 | 1000 | — | — |
| 2.18 | 22 | 1 + | 0 | 980 | 70; 110 | 95; 195 | >1000 | 0.4 | — |
| | | IKA | | | | | | | |
| 2.19 | 22 | 2 | 5 | 880 | — | 70 | >1000 | 0.2 | — |
| 2.20 | 23 | 2 | 0 | 850 | — | 180 | 1350 | 0 | — |
| 2.21 | 23 | 1 | 0 | 874 | — | 80 | 1500 | 0.1 | — |

*Pₘₐₓ − Pₘᵢₙ
#Pₘₐₓ > 4.75 kPa; Pₘᵢₙ = 1.25 kPa

The results in Table 3 clearly show that a significant window of coatability was obtained at coating speeds at or above 40 m/min with liquid compositions with a viscosity at the coating temperature (in this case 20° C.) and a shear rate of 100 s⁻¹ of at least 500 mPa·s, when the tan δ of the liquid composition at the coating head determined at the coating temperature, 1 Hz and a shear stress of 250 Pa is less than 1000.

These results also show that subjection of the dispersions to shear stress prior to their reaching the coating head results in an increase in tan δ i.e. a decrease in elasticity. This is shown by comparing the tan δ results for dispersion 2.9 and 2.10; 2.11 and 2.12; 2.13 and 2.14; 2.15 and 2.16; and 2.17 and 2.18, which clearly show that subjection of dispersions of 2.9, 2.11, 2.13, 2.15 and 2.17 to the shear stress resulting from mixing results in a significant increase in the tan δ.

Furthermore, although the tan δ values for the dispersions is not significantly changed upon standing for 24 hours in a holding tank, the tan δ values are significantly increased by shear stress resulting from the pumping, filtration and other shear stress inducing elements of the system transporting the dispersion to the coating head i.e. such transport results in a decrease in elasticity.

EXAMPLE 1 describes several experiments in which an attempt was made to simulate the shear stress experienced by a liquid composition in being transported to a slot extrusion coating head. Table 4 compares the actual increase in tan δ value upon being transported to the slot extrusion coating head with the increase in tan δ upon subjection to 90 s shear stress upon mixing at 1500 rpm.

The results in Table 4 show that the 90 s shear stress at 1500 s⁻¹ increased the tan δ value from 135 to 242 i.e. an increase of 79%, whereas the transport to the slot extrusion coating head increased the tan δ value from 135 to 520 i.e. an increase of 285%.

TABLE 4

| | | | | Tan δ of dispersion at shear stress of 250 Pa, 1 Hz & 20° C. | | | | |
|---|---|---|---|---|---|---|---|---|
| | | | viscosity | | after | after 90 s shear stress at 1500 s⁻¹ | | at coating |
| Disper- | | Disper- | at 20° C. & | fresh in | 24 h in | simulating transport to head | | head after |
| sion | Binder | sion | 100 s⁻¹ | holding | holding | immediately | 15 min | 24 h in |
| No. | No. | type | [Pa · s] | tank | tank | after shear | after shear | holding tank |
| 2.5 | 10 | 3 | 950 | 135 | 135 | 242 | 201 | 520 |

### EXAMPLE 3

20% by weight solutions of binders 3, 6 and 10 to 16 in 2-butanone were prepared. Complex viscosity measurements were then carried out on these solutions. In phase and 90° out of phase viscosity measurements were extracted from complex viscosity measurements carried out with a oscillatory rotary viscometer, the Anton Paar Physica MCR 501, with a CC27 concentric cylinder configuration with a TEZ 150P-C temperature control system at a shear stress of 250 Pa, on samples taken from the storage vessel at an oscillatory frequency of 1 Hz and 20° C. giving η′ and η″, the dynamic viscosity and storage viscosity respectively. G″ and G′ are related to the two dynamic viscosity coefficients η′ and η″, the dynamic viscosity and storage viscosity respectively. Since G″ and G′ are related to the two dynamic viscosity coefficients η′ and η″ via: G″=ωη′ and G′=ωη″, tan δ, being the ratio of G″ to G′, could be calculated. Values of tan δ above 1500 measured with the MCR 501 are unreliable and irreproducible, due to insufficient precision in the G′ value. The results are summarized in Table 5 together with the results for the 2-butanone emulsions prepared with the same binders from Table 1 of EXAMPLE 1.

TABLE 5

| | | 20% 2-butanone | | | | | |
|---|---|---|---|---|---|---|---|
| | | solution of binder | | | 2-butanone emulsion also containing AgBeh, | | |
| | | Viscosity | | | R01, R02, T03, S01, S02, S03 & S04 | | |
| | | at 100 s⁻¹ | tan δ at 250 Pa, | Disper- | | Viscosity at | tan δ at 250 Pa, |
| | Binder | & 20° C. | 1 Hz & 20° C. | sion | Binder | 100 s⁻¹ & 20° C. | 1 Hz & 20° C. |
| Solution | No. | [Pa · s] | (no pre-shear) | No. | No. | [Pa · s] | (no pre-shear) |
| 3.1 | 3 | 1.71 | 71 | 1.1 | 1 + 3 | 1.43 | 64 |
| 3.2 | 6 | 1.33 | 110.5 | 1.4 | 1 + 6 | 1.23 | 95 |
| 3.3 | 10 | 4.80 | 29 | 1.8 | 1 + 10 | 1.73 | 55 |
| 3.4 | 11 | 1.60 | 97 | 1.9 | 1 + 11 | 1.12 | 218 |
| | | (30 s⁻¹) | | | | | |
| 3.5 | 12 | 1.55 | 88 | 1.10 | 1 + 12 | 1.19 | 134 |
| | | (30 s⁻¹) | | | | | |
| 3.6 | 13 | 2.00 | 80 | 1.11 | 1 + 13 | 1.22 | 112 |
| | | (30 s⁻¹) | | | | | |
| 3.7 | 14 | 1.60 | 124 | 1.12 | 1 + 14 | 0.95 | 380 |
| 3.8 | 15 | 3.00 | 52 | 1.13 | 1 + 15 | 1.46 | 91 |
| 3.9 | 16 | 3.20 | 48 | 1.14 | 1 + 16 | 1.58 | 83 |

The results in Table 5 show that 20% by weight solutions of polyacetals exhibit viscosities at 20° C. and 100 s⁻¹ greater than 500 mPa·s and also tan δ values measured at a shear stress of 250 Pa, 1 Hz and 20° C. less than 1000, whereas the dispersions all exhibit lower viscosities at 20° C. and 100 s⁻¹ and higher or comparable tan δ values measured at a shear stress of 250 Pa, 1 Hz and 20° C.

### EXAMPLE 4

Dispersion 4.1 was prepared as described for dispersion type 1 in EXAMPLE 2 using binder No. 1 and two Dispersions 4.2 and 4.3 were prepared as described for dispersion type 1 in EXAMPLE 2, but with solids contents increased by 6 and 8% by weight respectively.

The viscosity of dispersions 4.1 to 4.3 was determined at 20° C. and 100 s⁻¹ and the window of coatability, ΔP, was determined empirically at coating speeds of 80 m/min and 90 m/min by varying the applied bead vacuum, P, and determining Pₘᵢₙ as the lowest bead vacuum at which air entrainment was not visually observed in the coating and Pₘₐₓ as the highest bead vacuum at which there was no bead break up resulting in “rivulets”. The window of coatability, ΔP, is Pₘₐₓ-Pₘᵢₙ. The results are summarized in Table 6 below.

TABLE 6

| | | | | Viscosity | | coating | | | |
|---|---|---|---|---|---|---|---|---|---|
| | | concentration | | at 20° C. & | wet-layer | speed | | | |
| Dispersion | Binder | increase | % | 100 s⁻¹ | thickness, | v | Pmin | Pmax | ΔP |
| nr | No. | [%] | solids | [mPa · s] | d (μm) | (m/min) | (kPa) | (kPa) | (kPa) |
| 4.1 | 1 | 0 | 27.2 | 1390 | 95 | 70 | 0.9 | 2.5 | 1.6 |
| 4.1 | 1 | 0 | 27.2 | 1390 | 95 | 90 | 1.85 | 3.4 | 1.55 |
| 4.2 | 1 | 6 vs 1.1 | 28.8 | 1790 | 95 | 70 | 1.0 | 2.85 | 1.85 |
| 4.2 | 1 | 6 vs 1.1 | 28.8 | 1790 | 95 | 80 | 1.48 | 4.6 | 3.12 |
| 4.2 | 1 | 6 vs 1.1 | 28.8 | 1790 | 95 | 90 | 1.9 | 4.6 | 2.7 |
| 4.3 | 1 | 8 vs 1.1 | 29.3 | 1880 | 95 | 70 | 1.15 | 2.8 | 1.65 |
| 4.3 | 1 | 8 vs 1.1 | 29.3 | 1880 | 95 | 80 | 1.65 | 4.4 | 2.75 |
| 4.3 | 1 | 8 vs 1.1 | 29.3 | 1880 | 95 | 90 | 2.2 | 4.6 | 2.4 |

Pₘᵢₙ increased with coating speed and at a given coating speed with dispersion concentration. AP varied between 1.6 kPa and 3.12 kPa.

Table 7 summarizes the compositions and characteristics of binders 1, 2, 18, 21, 22 and 23 from the table summarizing the binders and the tan δ of type 1 dispersion containing these binders at a shear stress of 250 Pa, 1 Hz and 20° C. measured on a sample taken from the coating head from Table 3.

The viscosity of concentrated solutions of the binder in the liquid carrier medium considerably influenced the tan δ values of the type 1 dispersion as is shown from Table 7 in which the tan δ values of the type 1 dispersion with the binders having similar compositions to binder No. 1 decrease with increasing viscosity of 30 wt % 2-butanone solutions of the binders at 10 s⁻¹ and 20° C. Although the polydispersity of the binder was also a factor, it is clear from Table 7 that type 1 dispersions with binder No. 1 had a tan δ value of ca. 120 or less, which is reflected in the very high windows of coatability (1.55 to 3.12 kPa) observed with type 1 dispersions with binder No. 1.

TABLE 7

| | | | | | | | | viscosity | tan δ of type 1 |
|---|---|---|---|---|---|---|---|---|---|
| | | | | | | | | of 30 wt % | dispersion at |
| | Vinyl | | | | | | | 2-butanone | shear stress of |
| | aceto- | vinyl | vinyl | vinyl | | | | solution at | 250 Pa, 1 Hz & |
| Binder | acetal | butyral | alcohol | acetate | Tg | | | 10 s⁻¹ & 20° C. | 20° C. at |
| No. | [mol %/wt %] | [mol %/wt %] | [mol %/wt %] | [mol %/wt %] | [° C.] | Mw × 10⁻³ | Mn × 10⁻³ | [Pa · s] | coating head |
| 1 | 0/0 | 66/85 | 32/13 | 2.2/1.7 | 62 | 122 | 36 | 4.84 | — |
| 2 | 0/0 | 62/83 | 36/15 | 2.1/1.7 | | 115 | 27.3 | 4.61 | 107 |
| 18 | 0/0 | 64/84.4 | 34/13.9 | 2.1/1.7 | | | | 4.09 | 150 |
| 21 | 0/0 | 66/85 | 33/13 | 2.0/1.6 | | | | 3.50 | 450 |
| 22 | 0/0 | 64/84 | 34/14 | 2.2/1.8 | | | | 3.715 | 1000 |
| 23 | 0/0 | 63/84 | 35/14 | 2.2/1.8 | | | | 3.59 | 1500 |

The present invention may include any feature or combination of features disclosed herein either implicitly or explicitly or any generalisation thereof irrespective of whether it relates to the presently claimed invention. In view of the foregoing description it will be evident to a person skilled in the art that various modifications may be made within the scope of the invention.

Having described in detail preferred embodiments of the current invention, it will now be apparent to those skilled in the art that numerous modifications can be made therein without departing from the scope of the invention as defined in the following claims.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Of course, variations of those preferred embodiments will become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

I claim:

1. A method for slot extrusion coating a liquid composition at a temperature and a coating speed at or above 40 m/min, said liquid composition having a viscosity of at least 500 mPa·s at said coating temperature and a shear rate of 100 s⁻¹, comprising the steps of:
(i) selecting said liquid composition for slot extrusion coating having a tan δ of less than 1000 measured by oscillatory dynamic viscosity measurements at 1 Hz, said coating temperature and a shear stress of 250 Pa under conditions in which there is effectively no variation in shear stress within said liquid composition during said measurement, said composition being selected from liquid compositions each comprising at least one binder and a liquid carrier medium; and
(ii) slot extrusion coating the composition via a slot onto a web support with a bead vacuum at said coating temperature and said coating speed.

2. The method according to claim 1, wherein said liquid composition has a tan δ of less than 200 measured by oscillatory dynamic viscosity measurements at 1 Hz, said coating temperature and a shear stress of 250 Pa under conditions in which there is effectively no variation in shear stress within said liquid composition during said measurement.

3. The method according to claim 1, wherein said at least one binder is a polyvinyl acetal.

4. The method according to claim 3, wherein said polyvinyl acetal is polyvinyl butyral or a copolymer comprising vinyl aceto-acetal and vinyl butyral units.

5. The method according to claim 1, wherein said liquid composition further comprises fine particles.

6. The method according to claim 1, wherein said liquid composition further comprises a substantially light-insensitive organic silver salt.

7. The method according to claim 1, wherein said liquid composition further comprises an organic reducing agent.

8. The method according to claim 1, wherein said method further comprises the step of drying and said resulting dried layer is a thermosensitive element of a thermographic recording material.

9. The method according to claim 1, wherein said liquid carrier medium is non-aqueous.

10. The method according to claim 1, wherein said liquid composition further comprises a colorant.

11. A method for selecting a liquid composition for slot extrusion coating at a coating temperature and a coating speed at or above 40 m/min, said liquid composition having a viscosity at said coating temperature of at least 500 mPa·s at a shear rate of 100 s⁻¹, comprising the step of:
(i) selecting said liquid composition for slot extrusion coating having a tan δ of less than 1000 measured by oscillatory dynamic viscosity measurements at 1 Hz, the coating temperature and a shear stress of 250 Pa under conditions in which there is effectively no variation in shear stress within said liquid composition during said measurement, said composition being selected from liquid compositions each comprising at least one binder and a liquid carrier medium.

12. The method according to claim 11, wherein said liquid composition has a tan δ of less than 200 measured by oscillatory dynamic viscosity measurements at 1 Hz, said coating temperature and a shear stress of 250 Pa under conditions in which there is effectively no variation in shear stress within said liquid composition during said measurement.

13. The method according to claim 11, wherein said at least one binder is a polyvinyl acetal.

14. The method according to claim 13, wherein said polyvinyl acetal is polyvinyl butyral or a copolymer comprising vinyl aceto-acetal and vinyl butyral units.

15. The method according to claim 11, wherein said liquid composition further comprises fine particles.

16. The method according to claim 11, wherein said liquid composition further comprises a substantially light-insensitive organic silver salt.

17. The method according to claim 11, wherein said liquid composition further comprises an organic reducing agent.

18. The method according to claim 11, wherein said liquid carrier medium is non-aqueous.

19. The method according to claim 11, wherein said liquid composition further comprises a colorant.
